(19) United States
(12) Patent Application Publication
(10) Pub. No.: US 2019/0304791 A1
(43) Pub. Date: Oct. 3, 2019

(54) Method of Manufacturing Semiconductor Device, Substrate Processing Apparatus and Non-transitory Computer-readable Recording Medium

(71) Applicant: Kokusai Electric Corporation, Tokyo (JP)

(72) Inventor: Motomu DEGAI, Toyama (JP)

(21) Appl. No.: 16/285,970

(22) Filed: Feb. 26, 2019

(30) Foreign Application Priority Data
Mar. 27, 2018 (JP) 2018-059822

(51) Int. Cl. H01L 21/285; H01L 21/28; C23C 16/34

(52) U.S. Cl. CPC H01L 21/28512; C23C 16/34; H01L 21/28088

(57) ABSTRACT

There is provided a technique that includes (a) forming halogen terminated sites on a surface of a substrate having a base film formed thereon by supplying a halogen-containing gas to the substrate; and (b) terminating the surface of the substrate with hydroxyl group by supplying a hydroxyl-containing gas containing

### CROSS REFERENCE TO RELATED APPLICATIONS

This application claims foreign priority under 35 U.S.C. § 119(a)-(d) to Application No. JP 2018-059822 filed on Mar. 27, 2018, the entire contents of which are hereby incorporated by reference.

### TECHNICAL FIELD

The present disclosure relates to a method of manufacturing a semiconductor device, a substrate processing apparatus and a non-transitory computer-readable recording medium.

### BACKGROUND

In recent years, semiconductor devices are highly integrated. In order to realize the high integration of the semiconductor devices, it is required to form a film extremely thin.

Circuits in the semiconductor devices are formed by stacking various kinds of films. In order to maintain the characteristics of the semiconductor devices, it is necessary to improve the characteristics of each of the films. In order to improve the characteristics of the films, it is necessary to improve the uniformity of the films to be manufactured.

### SUMMARY

Described herein is a technique capable of forming a semiconductor device with high film uniformity.

According to one aspect of the technique described herein, there is provided a method of manufacturing a semiconductor device including: (a) forming halogen terminated sites on a surface of a substrate having a base film formed thereon by supplying a halogen-containing gas to the substrate; and (b) terminating the surface of the substrate with hydroxyl group by supplying an a hydroxyl-containing gas containing an oxygen component and a hydrogen component to the substrate.

### BRIEF DESCRIPTION OF THE DRAWINGS

FIG. 1 schematically illustrates a semiconductor device having a three-dimensional structure in which electrodes are formed three-dimensionally.

FIG. 2 is a flowchart illustrating a specific process of forming the semiconductor device shown in FIG. 1.

FIG. 3A schematically illustrates a vertical cross-section of a wafer and films formed thereon after a hole forming step S110 of the specific process is performed and FIG. 3B schematically illustrates the wafer and the films viewed from above after the hole forming step S110 is performed.

FIG. 4A schematically illustrates a vertical cross-section of the wafer and the films formed thereon after a hole filling step S112 of the specific process is performed and FIG. 4B is a partial enlarged view of a stacked film 108 after the hole filling step S112 is performed

FIG. 5 schematically illustrates a vertical cross-section of the wafer and the films formed thereon after a sacrificial film removing step S114 of the specific process is performed

FIG. 6 is a diagram for explaining problems caused by non-uniform film composition.

FIG. 7A schematically illustrates a continuous film formed by merging adjacent nuclei as the nuclei grow slightly when the nucleation density is high at an initial stage of film formation and FIG. 7B schematically illustrates a discontinuous film formed without merging the adjacent nuclei when the nucleation density is low at the initial stage of the film formation.

FIG. 8A schematically illustrates OH-terminated sites by a hydroxyl group (OH group) used as adsorption sites and FIG. 8B schematically illustrates a defect site (dangling bond) with a broken bond used as the adsorption sites.

FIG. 9 schematically illustrates a vertical cross-section of a vertical type process furnace of a substrate processing apparatus preferably used in one or more embodiments described herein.

FIG. 10 schematically illustrates a cross-section taken along the line A-A of the vertical type process furnace of the substrate processing apparatus shown in FIG. 9.

FIG. 11 is a block diagram schematically illustrating a configuration of a controller and components controlled by the controller of the substrate processing apparatus preferably used in the embodiments.

FIG. 12 is a timing diagram illustrating a gas supply according to the embodiments.

FIG. 13A schematically illustrates a surface of the wafer 200 having the silicon oxide film formed thereon before the surface of the wafer 200 is exposed to WF₆ gas, FIG. 13B schematically illustrates the surface of the wafer 200 immediately after the WF₆ gas is supplied to the surface of the wafer 200, and FIG. 13C schematically illustrates the surface of the wafer 200 after the surface of the wafer 200 is exposed to the WF₆ gas.

FIG. 14A schematically illustrates the surface of the wafer 200 immediately after H₂O gas is supplied to the surface of the wafer 200, and FIG. 14B schematically illustrates the surface of the wafer 200 after the surface of the wafer 200 is exposed to the H₂O gas.

FIG. 15 illustrates an exemplary SEM image of a surface of a thermal oxide film after a TiN film is formed when the TiN film is formed on a base film having a low number density of the adsorption sites.

FIG. 16 illustrates the resistivity of the TiN film formed after a hydrofluoric acid processing and the resistivity of the TiN film formed after an annealing process at 800° C.

### DETAILED DESCRIPTION

### Embodiments According to Technique Described Herein

Hereinafter, one or more embodiments according to the technique will be described.

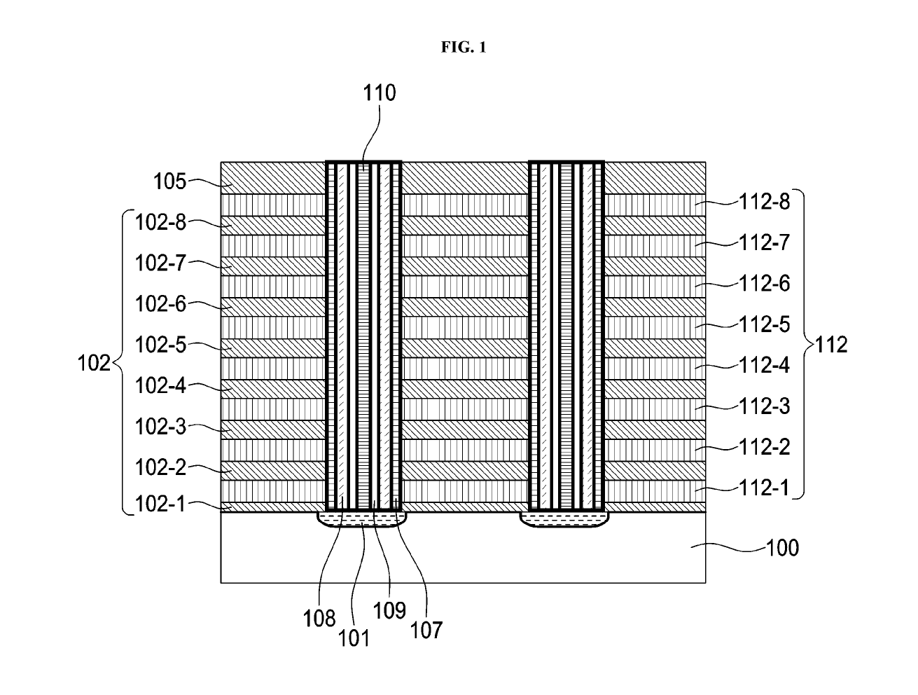

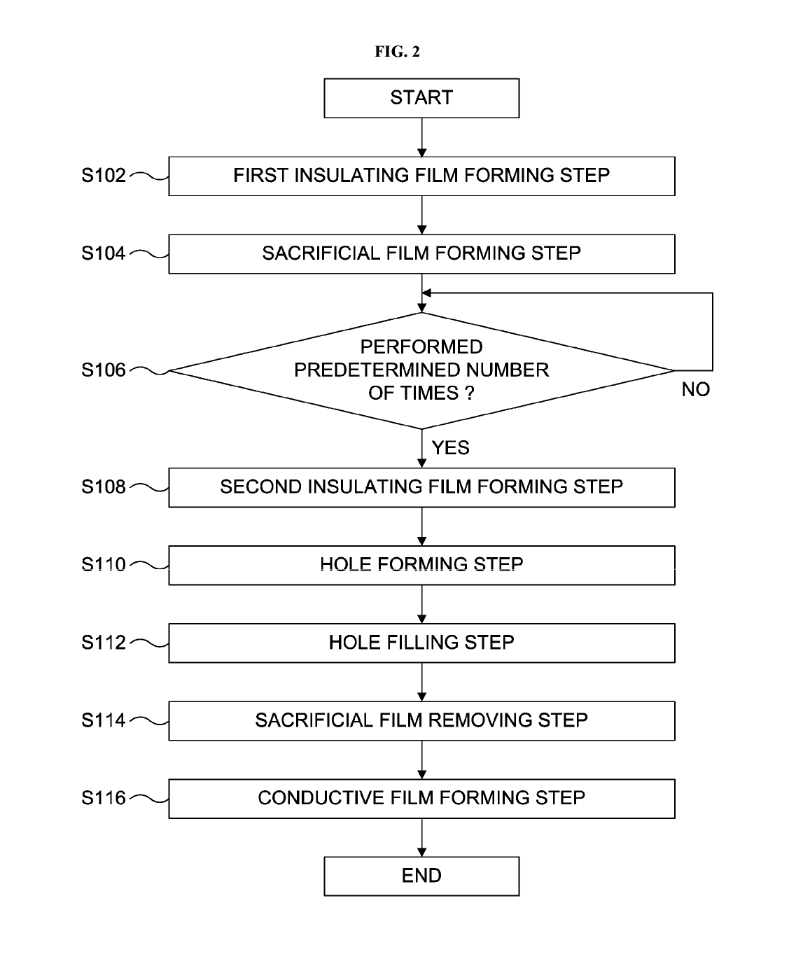

First, an exemplary structure of a device having a film formed using the technique will be described. The device is a semiconductor device having a three-dimensional structure in which electrodes are formed three-dimensionally. As shown in FIG. 1, the semiconductor device has the structure in which an insulating film 102 and a conductive film 112 serving as an electrode are alternately stacked on a wafer 100. Hereinafter, a specific process of forming the semiconductor device will be described in detail with reference to FIG. 2.

### First Insulating Film Forming Step S102

First, in the first insulating film forming step S102, the insulating film 102 is formed on the wafer 100 on which a common source line (CSL) 101 is formed. In the embodiments, the insulating film 102 is constituted by, for example, a silicon oxide (SiO₂) film. The SiO₂ film is formed by supplying a silicon-containing gas and an oxygen-containing gas onto the wafer 100 while heating the wafer 100 to a predetermined temperature.

### Sacrificial Film Forming Step S104

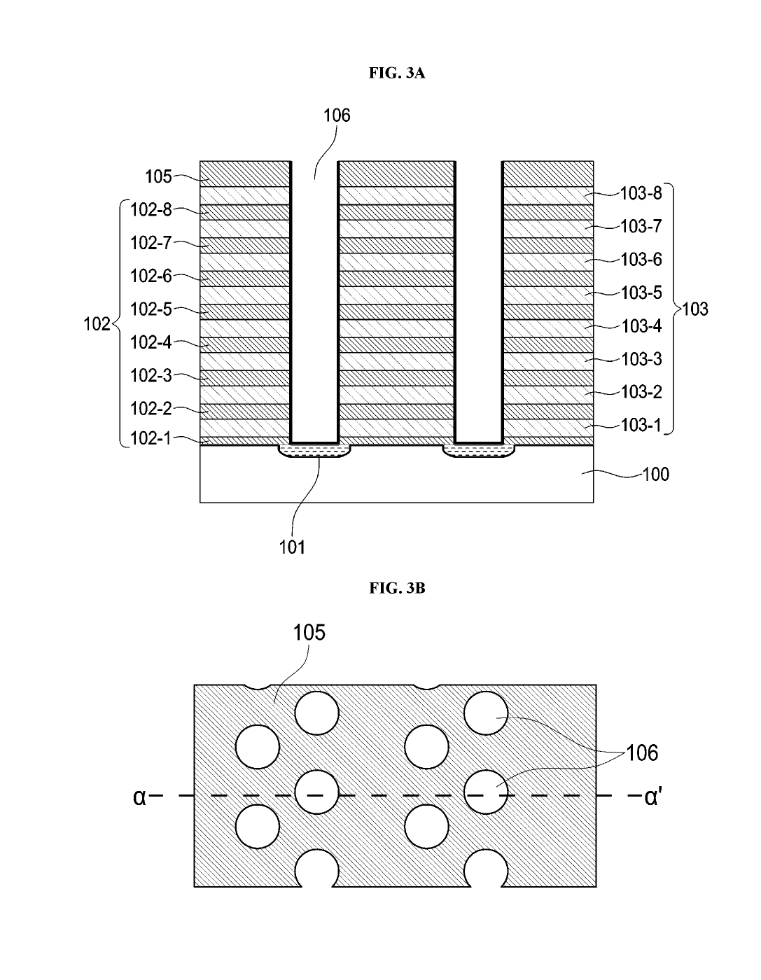

Subsequently, the sacrificial film forming step S104 will be described. In the sacrificial film forming step S104, as shown in FIG. 3A, a sacrificial film 103 is formed on the insulating film 102 formed on the wafer 100. The sacrificial film 103 is removed in a sacrificial film removing step S114 to be described later, and has etching selectivity with respect to the insulating film 102. In the present specification, “the sacrificial film 103 has the etching selectivity with respect to the insulating film 102” means that the sacrificial film 103 is etched while the insulating film 102 is not etched when they are exposed to an etching solution.

The sacrificial film 103 is constituted by, for example, a silicon nitride (SiN) film. The SiN film is formed by supplying the silicon-containing gas and a nitrogen-containing gas onto the wafer 100 while heating the wafer 100 to a predetermined temperature. Details will be described later.

### Determination Step S106

Subsequently, in the determination step S106, it is determined whether or not a combination of the first insulating film forming step S102 and the sacrificial film forming step S104 is performed a predetermined number of times. That is, it is determined whether or not a predetermined number of combinations of the insulating film 102 and the sacrificial film 103 shown in FIG. 1 are stacked. In the embodiments, for example, the predetermined number of combinations stacked on the wafer 100 is 8. Hereinafter, the embodiments will be described by way of an example in which 8 layers of the insulating film 102 (that is, the insulating films 102-1, 102-2, 102-3, 102-4, 102-5, 102-6, 102-7 and 102-8) and 8 layers of the sacrificial film 103 (that is, the sacrificial films 103-1, 103-2, 103-3, 103-4, 103-5, 103-6, 103-7 and 103-8) are alternately formed.

When it is determined that the combination of the first insulating film forming step S102 and the sacrificial film forming step S104 is not performed the predetermined number of times (“NO” in FIG. 2), the first insulating film forming step S102 and the sacrificial film forming step S104 are performed again. When it is determined that the combination of the first insulating film forming step S102 and the sacrificial film forming step S104 is performed the predetermined number of times (“YES” in FIG. 2), a second insulating film forming step S108 is performed.

### Second Insulating Film Forming Step S108

Subsequently, an insulating film 105 is further formed on the insulating film 102 and the sacrificial film 103 formed with 8 layers. The insulating film 105 is formed by the same method as the insulating film 102, and is formed on the sacrificial film 103.

### Hole Forming Step S110

Subsequently, the hole forming step S110 will be described with reference to FIGS. 3A and 3B. FIG. 3A schematically illustrates a vertical cross-section of the wafer 100 and the films 102, 103 and 105 formed thereon after the hole forming step S110 is performed similar to FIG. 1, and FIG. 3B schematically illustrates the wafer 100 and the films 102, 103 and 105 viewed from above after the hole forming step S110 is performed. FIG. 3A corresponds to a cross-section taken along the line a-a′ of the wafer 100 and the films 102, 103 and 105 shown in FIG. 3B.

In the hole forming step S110, a hole 106 is formed in a stacked structure of the insulating films 102 and 105 and the sacrificial film 103. As shown in FIG. 3A, the hole 106 is formed so as to expose the CSL 101 at the bottom thereof. In addition, one or more holes 106 may be provided in the stacked structure as shown in FIG. 3B.

### Hole Filling Step S112

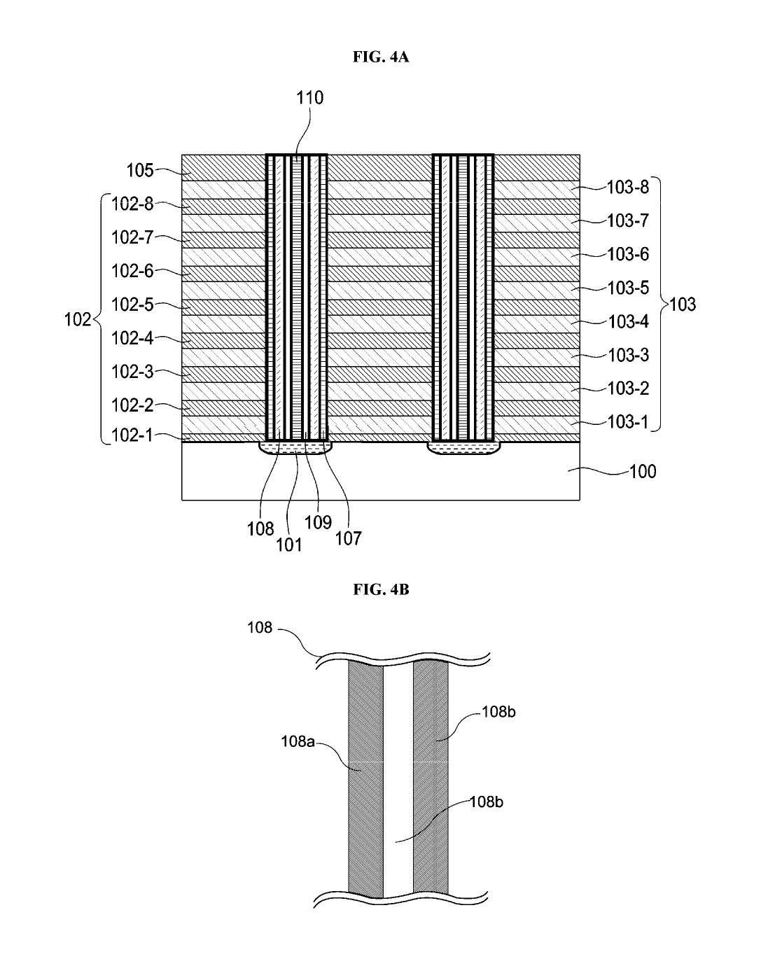

Subsequently, the hole filling step S112 will be described with reference to FIG. 4. In the hole filling step S112, the hole 106 formed in the hole forming step S110 is filled with films such as a stacked film 108. Specifically, a protective film 107 such as a metal oxide (Al₂O₃) film, the stacked film 108, a channel polysilicon film 109 and a filling insulating film 110 such as a silicon oxide (SiO₂) film are formed in the hole 106 from the side wall surface toward the center of the hole 106. The protective film 107, the stacked film 108, the channel polysilicon film 109 and the filling insulating film 110 are cylindrical.

The stacked film 108 is constituted mainly by an inter-electrode insulating film 108a such as a silicon oxide (SiO₂) film, a charge trapping film 108b such as a silicon nitride (SiN) film and a tunnel insulating film 108c such as a silicon oxide (SiO₂) film. The inter-electrode insulating film 108a is provided between the protective film 107 and the charge trapping film 108b. The tunnel insulating film 108c is provided between the charge trapping film 108b and the channel polysilicon film 109.

The charge trapping film 108b has the same composition as that of the sacrificial film 103. Therefore, the charge trapping film 108b may be removed with the sacrificial film 103 when the sacrificial film 103 is removed. The protective film 107 is provided on the side wall surface of the hole 106 to prevent the charge trapping film 108b from being removed.

### Sacrificial Film Removing Step S114

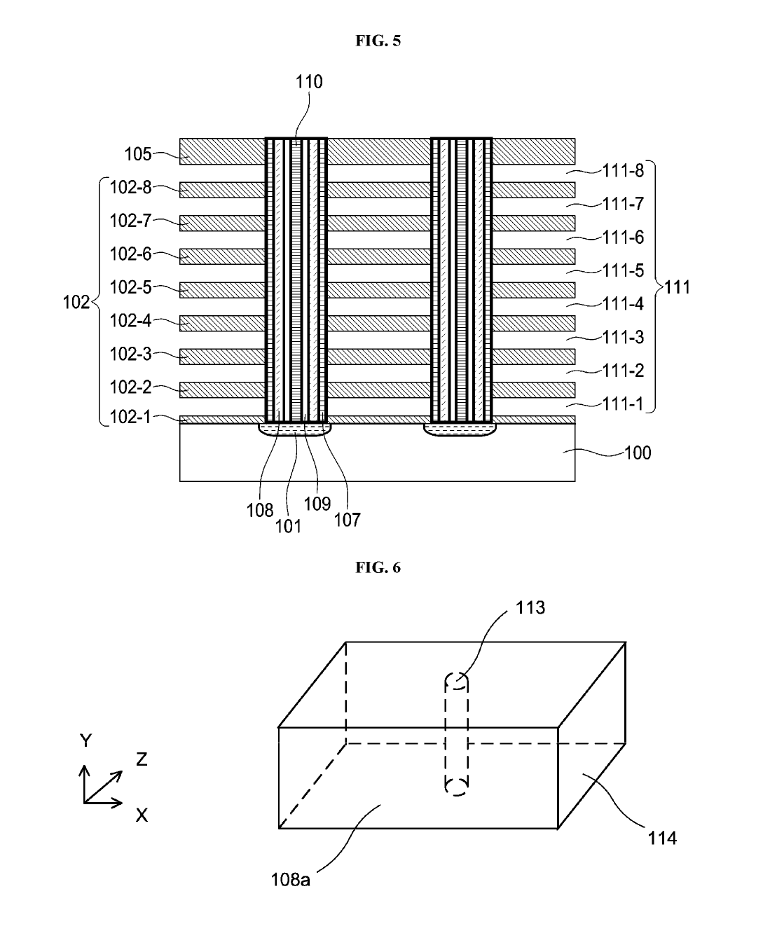

Subsequently, the sacrificial film removing step S114 will be described with reference to FIG. 5. In the sacrificial film removing step S114, the sacrificial film 103 is removed by wet etching. As a result of removing the sacrificial film 103, a void 111 is provided at a position where the sacrificial film 103 is removed. That is, voids 111-1, 111-2, 111-3, 111-4, 111-5, 111-6, 111-7 and 111-8 are provided at positions where the sacrificial films 103-1 through 103-8 are removed.

### Conductive Film Forming Step S116

Subsequently, the conductive film forming step S116 will be described with reference to FIG. 1. In the conductive film forming step S116, the conductive film 112 serving as an electrode later is formed in the void 111 formed in the sacrificial film removing step S114. The conductive film 112 is made of a material such as tungsten, for example. By forming the conductive film 112 as described above, the semiconductor device as shown in FIG. 1 is formed.

In the structure described above, for example, it is required to form the films filled in the hole 106 (that is, the protective film 107, the stacked film 108, the channel polysilicon film 109 and the filling insulating film 110) extremely thin.

When the extremely thin films are used in the structure of the semiconductor device, the characteristics of each of the extremely thin films such as resistance value and charge mobility are required to be uniform. In order to make the characteristics uniform, it is necessary to improve the uniformity of the film composition of each of the extremely thin films.

Subsequently, problems caused by non-uniform film composition will be described with reference to FIG. 6. FIG. 6 is a diagram for explaining the problems by taking the inter-electrode insulating film 108a as an example. Referring to FIG. 6, a low density portion 113 and a high density portion 114 exist in the inter-electrode insulating film 108a. The low density portion 113 is a portion of the inter-electrode insulating film 108a having a film composition density lower than a desired film composition density. The low density portion 113 is also referred to as a “pinhole”. The high density portion 114 is a portion of the inter-electrode insulating film 108a satisfying the desired film composition density. The film composition density of the low density portion 113 is lower than that of the high density portion 114.

As described above, the inter-electrode insulating film 108a is provided adjacent to the charge trapping film 108b. That is, in FIG. 6, the inter-electrode insulating film 108a is provided adjacent to the charge trapping film 108b in the XY-plane. When the inter-electrode insulating film 108a has a predetermined film composition density, the inter-electrode insulating film 108a is capable of suppressing the leakage current from the charge trapping film 108b. However, when the film composition density of the inter-electrode insulating film 108a is lower than the predetermined film composition density, the leakage current occurs. That is, although the leakage current may not occur in the high density portion 114, the leakage current may occur in the low density portion 113.

In addition to the problems described above based on the inter-electrode insulating film 108a in FIG. 6, problems when a film composition of a metal film used for components such as a circuit is non-uniform will be described. When the metal film is used, for example, an insulating film is formed so as to be adjacent to the metal film in the XY-plane. Therefore, electric charges flowing in the metal film flow in the X-axis direction. Since the resistance values of the high density portion 114 and the low density portion 113 are different, the amount of electric charges flowing in the metal film may be different or the flow of electric charges may be disturbed.

When the film composition density varies as described above, the characteristics of the semiconductor device may deteriorate.

Subsequently, the cause of the variation in the film composition density will be described. The inventors of the present application discovered that the film composition density becomes non-uniform, for example, when adsorption sites in a base film (also referred to as an “underlying film”) are discontinuous.

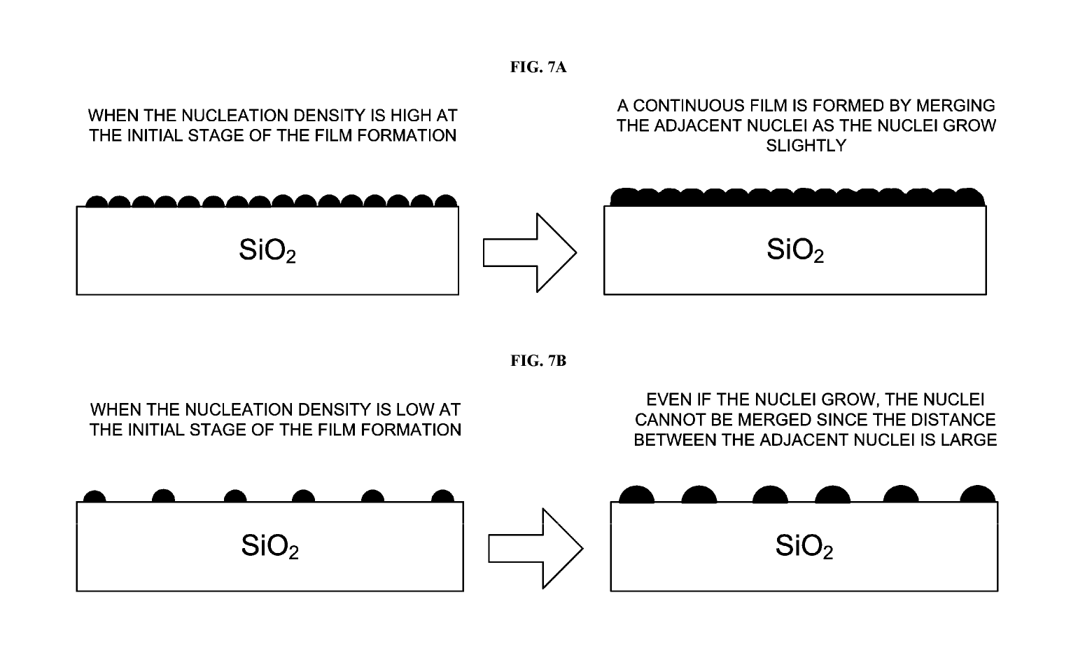

First, the reason that the film is formed discontinuously will be described with reference to FIGS. 7A and 7B. FIGS. 7A and 7B schematically illustrate an example in which the film is formed on a silicon oxide film. The film is grown by the following steps:

(i) adsorbing source molecules to the adsorption sites;

(ii) forming minute nuclei as constituent elements of the film by using the adsorbed source molecules as triggers;

(iii) growing the nuclei; and

(iv) merging adjacent nuclei while the nuclei are growing.

As shown in FIG. 7A, when the nucleation density is high at an initial stage of the film formation, a continuous film is formed by merging the adjacent nuclei as the nuclei grow slightly.

However, as shown in FIG. 7B, when the nucleation density is low at the initial stage of the film formation, even if the nuclei grow, the nuclei cannot be merged since the distance between the adjacent nuclei is large. Therefore, a discontinuous film is formed. As described above, in order to form the continuous film, it is important that the nucleation density at the initial stage of the film formation is high.

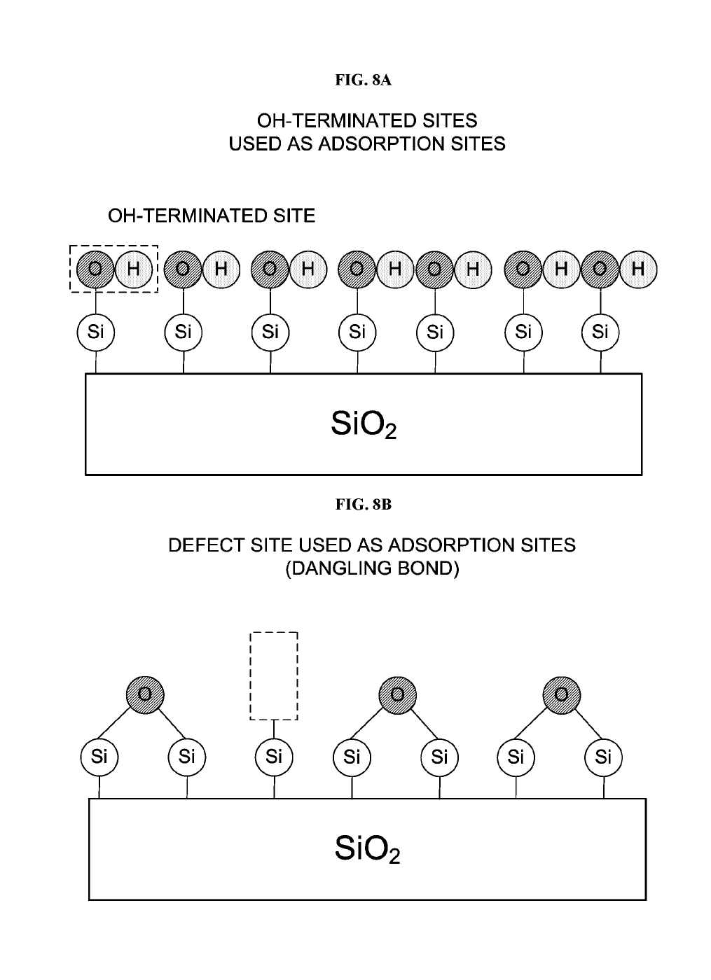

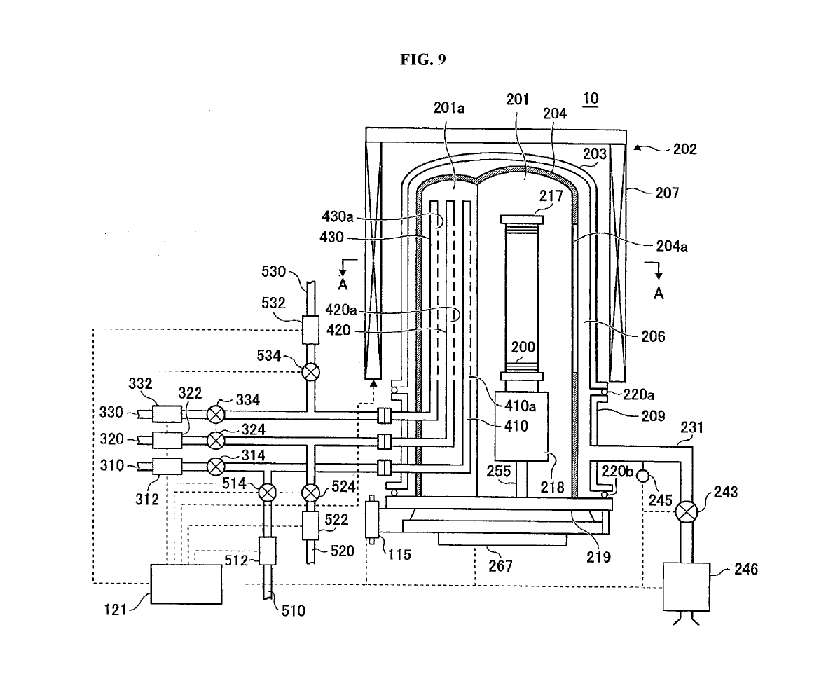

In order to increase the nucleation density at the initial stage of the film formation, it is required to increase a number density of the adsorption sites of the base film (also referred to as an “underlying film”) adsorbed by the source molecules in the step (i) which is a part of the above described steps for growing the film. Sites such as a site terminated by a hydroxyl group (also referred to as an “OH group”) as shown in FIG. 8A and a defect site (dangling bond) where a bond is broken as shown in FIG. 8B may be used as the adsorption sites of the source molecules. In the embodiments, the site terminated by the hydroxyl group is also referred to as an “OH-terminated site”.

The number density of the adsorption sites of the base film may be lowered, for example, by decomposed precursors bonded to the adsorption sites coming into contact with the base film when the film is formed on the base film. For example, the adsorption sites may bond with the decomposed precursors, or the adsorption sites may become empty when the decomposed precursors contact the base film.

A process such as an annealing process may be performed to modify the base film. However, a part of the adsorption sites may be removed by the annealing process and the distance between the adsorption sites may be lengthened. However, it is difficult to adjust the interval between the adsorption sites as intended. Therefore, the variations may occur in the adsorption sites. That is, the number density of the adsorption sites is lowered.

Therefore, in the technique described herein, the number density of the adsorption sites is increased and the composition density of the film to be formed is made uniform. Details will be described below.

### Substrate Processing Apparatus 10 According to One or More Embodiments Described Herein

Hereinafter, one or more embodiments according to the technique will be described with reference to FIGS. 9 through 12. The substrate processing apparatus 10 is an exemplary apparatus used in manufacturing processes of the semiconductor device. In the following description, the embodiments will be described by way of an example in which a titanium nitride (TiN) film is formed as the film on a silicon oxide (SiO₂) film. As described above, it is difficult to generate the defect site as intended as shown in FIG. 8B as one of the adsorption sites. Therefore, in the embodiments, OH-terminated sites with the hydroxyl group (OH group) as shown in FIG. 8A are generated on a surface of the silicon oxide film as the adsorption sites.

### (1) Configuration of Substrate Processing Apparatus

The substrate processing apparatus 10 includes a process furnace 202. The process furnace 202 is provided with a heater 207 serving as a heating apparatus (also referred to as a “heating mechanism” or a “heating system”). The heater 207 is cylindrical and provided in upright manner while being supported by a heater base (not shown) serving as a support plate.

An outer tube 203 constituting a reaction vessel (also referred to as a “process vessel”) is provided on an inner side of the heater 207 so as to be concentric with the heater 207. For example, the outer tube 203 is made of a heat resistant material such as quartz (SiO₂) and silicon carbide (SiC). The outer tube 203 is cylindrical with a closed upper end and an open lower end. A manifold (also referred to as an “inlet flange”) 209 is provided under the outer tube 203 so as to be concentric with the outer tube 203. The manifold 209 is made of a metal such as stainless steel (SUS). The manifold 209 is cylindrical with open upper and lower ends. An O-ring 220a serving as a sealing part is provided between the upper end of the manifold 209 and the outer tube 203. As the manifold 209 is supported by the heater base, the reaction tube 203 is installed to be perpendicular to the heater 207.

An inner tube 204 constituting the reaction vessel is provided on an inner side of the outer tube 203. The inner tube 204 is made of a heat resistant material such as quartz (SiO₂) and silicon carbide (SiC). The inner tube 204 is cylindrical with a closed upper end and an open lower end. The process vessel (the reaction vessel) is constituted mainly by the outer tube 203, the inner tube 204 and the manifold 209. A process chamber 201 is provided in a hollow cylindrical portion (an inside of the inner tube 204) of the process vessel.

The process chamber 201 is configured to accommodate vertically arranged wafers including a wafer 200 serving as a substrate in a horizontal orientation in a multistage manner by a boat 217 to be described later.

Nozzles 410, 420 and 430 are provided in the process chamber 201 so as to penetrate sidewalls of the manifold 209 and the inner tube 204. Gas supply pipes 310, 320 and 330 are connected to the nozzles 410, 420 and 430, respectively. However, the process furnace 202 according to the embodiments is not limited thereto.

MFCs (Mass Flow Controllers) 312, 322 and 332 serving as flow rate controllers (flow rate control mechanisms) are sequentially installed at the gas supply pipes 310, 320 and 330, respectively, from the upstream sides to the downstream sides of the gas supply pipes 310, 320 and 330. Valves 314, 324 and 334 serving as opening/closing valves are sequentially installed at the gas supply pipes 310, 320 and 330, respectively, from the upstream sides to the downstream sides of the gas supply pipes 310, 320 and 330. Gas supply pipes 510, 520 and 530 configured to supply an inert gas are connected to the gas supply pipes 310, 320 and 330 at the downstream sides of the valves 314, 324 and 334, respectively. MFCs 512, 522 and 532 serving as flow rate controllers (flow rate control mechanisms) and valves 514, 524 and 534 serving as opening/closing valves are sequentially installed at the gas supply pipes 510, 520 and 530, respectively, from the upstream sides to the downstream sides of the gas supply pipes 510, 520 and 530.

The nozzles 410, 420 and 430 are connected to front ends of the gas supply pipes 310, 320 and 330, respectively. The nozzles 410, 420 and 430 may include L-shaped nozzles. Horizontal portions of the nozzles 410, 420 and 430 are installed through sidewalls of the manifold 209 and the inner tube 204. Vertical portions of the nozzles 410, 420 and 430 protrude outward from the inner tube 204 and are installed in a spare chamber 201a having a channel shape (a groove shape) extending in the vertical direction. That is, the vertical portions of the nozzles 410, 420 and 430 are installed in the spare chamber 201a toward the top of the inner tube 204 (in the direction in which the wafers including the 200 are stacked) and along inner walls of the inner tube 204.

The nozzles 410, 420 and 430 extend from a lower region of the process chamber 201 to an upper region of the process chamber 201. The nozzles 410, 420 and 430 are provided with gas supply holes 410a, 420a and 430a facing the wafers including the 200, respectively, such that the process gases are supplied to the wafers through the gas supply holes 410a, 420a and 430a of the nozzles 410, 420 and 430. The gas supply holes 410a, 420a and 430a are provided so as to correspond to a lower region to an upper region of the inner tube 204, and have the same opening area and the same pitch. However, the gas supply holes 410a, 420a and 430a are not limited thereto. The opening areas of the gas supply holes 410a, 420a and 430a may gradually increase from the lower region toward the upper region of the inner tube 204 to maintain the uniformity of the amounts of gases supplied through the gas supply holes 410a, 420a and 430a.

The gas supply holes 410a, 420a and 430a of the nozzles 410, 420 and 430 are provided to correspond to a lower portion to an upper portion of the boat 217 to be described later. Therefore, the process gases supplied into the process chamber 201 through the gas supply holes 410a, 420a and 430a of the nozzles 410, 420 and 430 are supplied onto the wafers including the wafer 200 accommodated in the boat 217 from the lower portion to the upper portion thereof, that is, the entirety of the wafers accommodated in the boat 217. The nozzles 410, 420 and 430 extend from the lower region to the upper region of the process chamber 201. However, the nozzles 410, 420 and 430 may extend only to the vicinity of a ceiling of the boat 217.

A halogen-containing gas containing a halogen element such as tungsten hexafluoride (WF₆) or a source gas containing a metal element (also referred to as a “metal-containing gas”) such as titanium tetrachloride (TiCl₄), which is one of the process gases, is supplied into the process chamber 201 through the gas supply pipe 310 provided with the MFC 312 and the valve 314 and the nozzle 410.

A gas containing an oxygen component and hydrogen component (also referred to as an “hydroxyl-containing gas”) such as a water vapor (H₂O) gas, which is one of the process gases, is supplied into the process chamber 201 through the gas supply pipe 320 provided with the MFC 322 and the valve 324 and the nozzle 420. The hydroxyl-containing gas may also be referred to as an “OH-containing gas”.

A reactive gas, which is one of the process gases, is supplied into the process chamber 201 through the gas supply pipe 330 provided with the MFC 332 and the valve 334 and the nozzle 430. For example, a nitrogen (N)-containing gas containing nitrogen (N) may be used as the reactive gas. For example, ammonia (NH₃) gas may be used as the nitrogen-containing gas.

An inert gas, such as nitrogen (N₂) gas, is supplied into the process chamber 201 via the gas supply pipes 510, 520 and 530 provided with the MFCs 512, 522 and 532 and the valves 514, 524 and 534, and the nozzles 410, 420 and 430, respectively. While the embodiments will be described by way of an example in which the N₂ gas is used as the inert gas, the inert gas according to the embodiments is not limited thereto. For example, rare gases such as argon (Ar) gas, helium (He) gas, neon (Ne) gas and xenon (Xe) gas may be used as the inert gas instead of the N₂ gas.

While a process gas supply system may be constituted mainly by the gas supply pipes 310, 320 and 330, the MFCs 312, 322 and 332, the valves 314, 324 and 334, and the nozzles 410, 420 and 430, only the nozzles 410, 420 and 430 may be considered as the process gas supply system. The process gas supply system may be simply referred to as a “gas supply system”. When the source gas is supplied through the gas supply pipe 310, a source gas supply system may be constituted mainly by the gas supply pipe 310, the MFC 312 and the valve 314. The source gas supply system may further include the nozzle 410. When the halogen-containing gas is supplied through the gas supply pipe 310, a halogen-containing gas supply system may be constituted mainly by the gas supply pipe 310, the MFC 312 and the valve 314. The halogen-containing gas supply system may further include the nozzle 410. When a reducing gas such as the water vapor (H₂O) gas is supplied through the gas supply pipe 320, a reducing gas supply system may be constituted mainly by the gas supply pipe 320, the MFC 322 and the valve 324. The reducing gas supply system may further include the nozzle 420. When the hydroxyl-containing gas (that is, OH-containing gas) is supplied through the gas supply pipe 320, a hydroxyl-containing gas supply system may be constituted mainly by the gas supply pipe 320, the MFC 322 and the valve 324. The hydroxyl-containing gas supply system may further include the nozzle 420. The hydroxyl-containing gas supply system may also be referred to as an “OH-containing gas supply system”. When the reactive gas such is supplied through the gas supply pipe 330, a reactive gas supply system may be constituted mainly by the gas supply pipe 330, the MFC 332 and the valve 334. The reactive gas supply system may further include the nozzle 430. When the reactive gas such as the nitrogen-containing gas is supplied through the gas supply pipe 330, the reactive gas supply system may also be referred to as a “nitrogen-containing gas supply system”. An inert gas supply system may be constituted mainly by the gas supply pipes 510, 520 and 530, the MFCs 512, 522 and 532, and the valves 514, 524 and 534.

According to the embodiments, a gas is supplied into a vertically long annular space which is defined by the inner walls of the inner tube 204 and the edges (peripheries) of the wafers including the wafer 200 through the nozzles 410, 420 and 430 provided in the spare chamber 201a. The gas is injected into the inner tube 204 around the wafers through the gas supply holes 410a, 420a and 430a provided at the nozzles 410, 420 and 430 and facing the wafers, respectively. Specifically, the gas such as the source gas is injected into the inner tube 204 in a direction parallel to the surfaces of the wafers including the wafer 200 through the gas supply holes 410a, 420a and 430a of the nozzles 410, 420 and 430, respectively.

An exhaust hole (exhaust port) 204a facing the nozzles 410, 420 and 430 is provided in the sidewall of the inner tube 204 opposite to the spare chamber 201a. For example, the exhaust hole 204a may have a narrow slit shape elongating vertically. The gas supplied into the process chamber 201 through the gas supply holes 410a, 420a and 430a of the nozzles 410, 420 and 430 flows through the surfaces of the wafers including the wafer 200, and then is exhausted through the exhaust hole 204a into an exhaust channel 206 which is a gap provided between the inner tube 204 and the outer tube 203. The gas flowing in the exhaust channel 206 flows into an exhaust pipe 231 and is then discharged out of the process furnace 202.

The exhaust hole 204a is provided to face the wafers including the wafer 200. The gas supplied in the vicinity of the wafers in the process chamber 201 through the gas supply holes 410a, 420a and 430a flows in the horizontal direction (that is, a direction parallel to the surfaces of the wafers), and then is exhausted through the exhaust hole 204a into the exhaust channel 206. The exhaust hole 204a is not limited to a slit-shaped through-hole. For example, the exhaust hole 204a may include a plurality of holes.

The exhaust pipe 231 configured to exhaust an inner atmosphere of the process chamber 201 is provided at the manifold 209. A vacuum pump 246 serving as a vacuum exhaust apparatus is connected to the exhaust pipe 231 through a pressure sensor 245 and an APC (Automatic Pressure Controller) valve 243. The pressure sensor 245 serves as a pressure detector (pressure detection mechanism) to detect an inner pressure of the process chamber 201. With the vacuum pump 246 in operation, the APC valve 243 may be opened/closed to vacuum-exhaust the process chamber 201 or stop the vacuum exhaust. With the vacuum pump 246 in operation, the opening degree of the APC valve 243 may be adjusted in order to control the inner pressure of the process chamber 201. An exhaust system (also referred to as an “exhaust part”) may be constituted mainly by the exhaust hole 204a, the exhaust channel 206, the exhaust pipe 231, the APC valve 243 and the pressure sensor 245. The exhaust system may further include the vacuum pump 246.

A seal cap 219, serving as a furnace opening cover capable of sealing a lower end opening of the manifold 209 in airtight manner, is provided under the manifold 209. The seal cap 219 is in contact with the lower end of the manifold 209 from thereunder. The seal cap 219 is made of a metal such as SUS, and is disk-shaped. An O-ring 220b, serving as a sealing part and being in contact with the lower end of the manifold 209, is provided on an upper surface of the seal cap 219. A rotating mechanism 267 configured to rotate the boat 217 accommodating the wafers including the wafer 200 is provided at the seal cap 219 opposite to the process chamber 201. A rotating shaft 255 of the rotating mechanism 267 is connected to the boat 217 through the seal cap 219. As the rotating mechanism 267 rotates the boat 217, the wafers including the wafer 200 are rotated. The seal cap 219 may be moved upward/downward in the vertical direction by a boat elevator 115 provided outside the outer tube 203 vertically and serving as an elevating mechanism. When the seal cap 219 is moved upward/downward by the boat elevator 115, the boat 217 may be loaded into the process chamber 201 or unloaded out of the process chamber 201. The boat elevator 115 serves as a transfer device (transfer mechanism) that loads the boat 217, that is, the wafers including the wafer 200 into the process chamber 201 or unloads the boat 217, that is, the wafers including the wafer 200 out of the process chamber 201.

The boat 217 serving as a substrate retainer supports the wafers including the wafer 200, (for example, 25 to 200 wafers), which are concentrically arranged in the vertical direction and in horizontally orientation. The boat 217 is made of a heat resistant material such as quartz and SiC. An insulating plate 218 is provided under the boat 217 in multi-stages. The insulating plate 218 is made of a heat resistant material such as quartz and SiC. The insulating plate 218 suppresses the transmission of heat from the heater 207 to the seal cap 219. However, the embodiments are not limited thereto. For example, instead of the insulating plate 218, a heat insulating cylinder (not shown) may be provided as a cylindrical part made of a heat resistant material such as quartz and SiC.

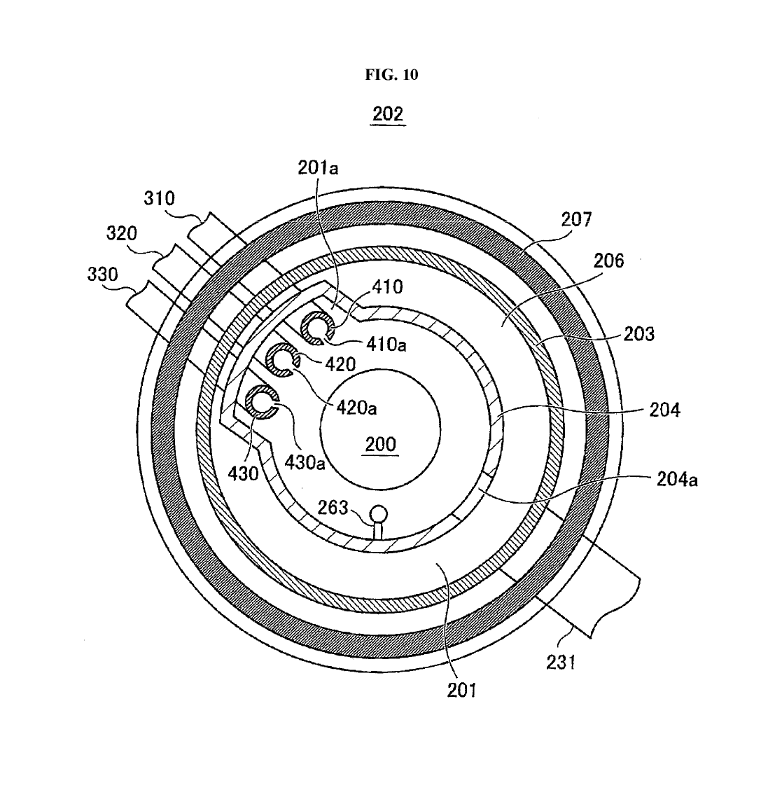

As shown in FIG. 10, a temperature sensor 263 serving as a temperature detector is installed in the inner tube 204. The amount of current supplied to the heater 207 is adjusted based on the temperature detected by the temperature sensor 263 such that the inner temperature of the process chamber 201 has a desired temperature distribution. The temperature sensor 263 is L-shaped like the nozzles 410, 420 and 430, and provided along the inner wall of the inner tube 204.

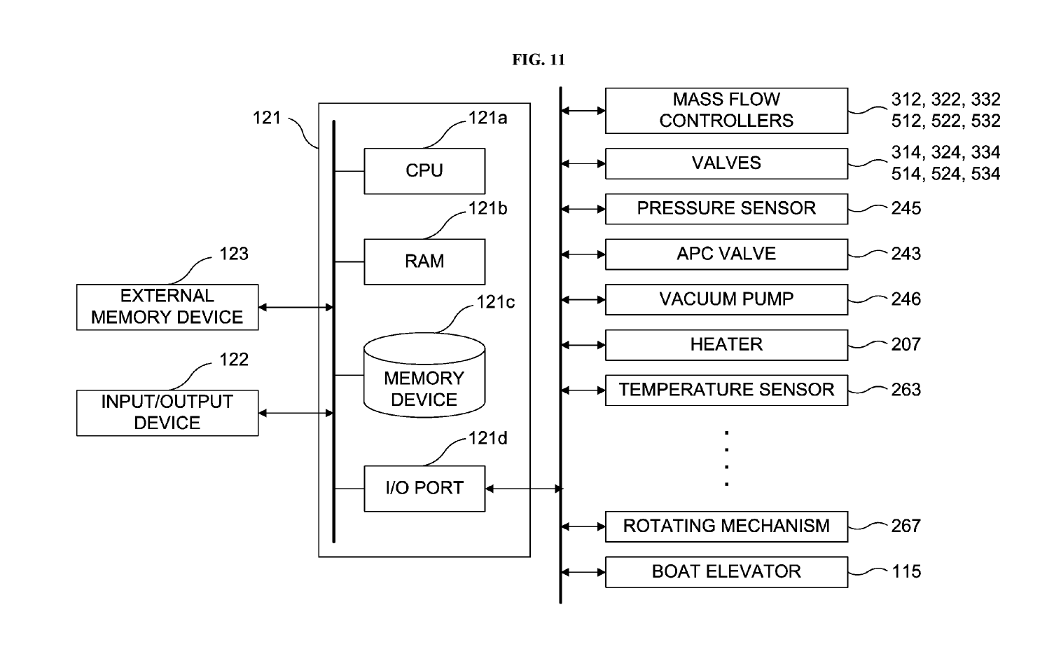

As shown in FIG. 11, a controller 121 serving as a control device (control mechanism) is embodied by a computer including a CPU (Central Processing Unit) 121a, a RAM (Random Access Memory) 121b, a memory device 121c and an I/O port 121d. The RAM 121b, the memory device 121c and the I/O port 121d may exchange data with the CPU 121a through an internal bus. For example, an input/output device 122 such as a touch panel is connected to the controller 121.

The memory device 121c is embodied by components such as a flash memory and HDD (Hard Disk Drive). A control program for controlling the operation of the substrate processing apparatus 10 or a process recipe containing information on the sequences and conditions of a method of manufacturing a semiconductor device described later is readably stored in the memory device 121c. The process recipe is obtained by combining steps of the method of manufacturing the semiconductor device described later such that the controller 121 can execute the steps to acquire a predetermine result, and functions as a program. Hereafter, the process recipe and the control program are collectively referred to as a “program”. In the present specification, the term “program” may indicate only the process recipe, indicate only the control program, or indicate both of them. The RAM 121b functions as a work area where a program or data read by the CPU 121a is temporarily stored.

The I/O port 121d is connected to the above-described components such as the MFCs 312, 322, 332, 512, 522 and 532, the valves 314, 324, 334, 514, 524 and 534, the pressure sensor 245, the APC valve 243, the vacuum pump 246, the heater 207, the temperature sensor 263, the rotating mechanism 267 and the boat elevator 115.

The CPU 121a is configured to read the control program from the memory device 121c and execute the read control program. Furthermore, the CPU 121a is configured to read a recipe such as the process recipe from the memory device 121c according to an operation command inputted from the input/output device 122. According to the contents of the read recipe, the CPU 121a may be configured to control various operations such as flow rate adjusting operations for various gases by the MFCs 312, 322, 332, 512, 522 and 532, opening/closing operations of the valves 314, 324, 334, 514, 524 and 534, an opening/closing operation of the APC valve 243, a pressure adjusting operation by the APC valve 243 based on the pressure sensor 245, a temperature adjusting operation of the heater 207 based on the temperature sensor 263, a start and stop of the vacuum pump 246, a rotation operation and rotation speed adjusting operation of the boat 217 by the rotating mechanism 267, an elevating operation of the boat 217 by the boat elevator 115, and a transport operation of the wafer 200 to the boat 217.

The controller 121 may be embodied by installing the above-described program stored in an external memory device 123 into a computer. For example, the external memory device 123 may include a magnetic disk such as a hard disk and a flexible disk, an optical disk such as CD and DVD, a magneto-optical disk such as MO, and a semiconductor memory such as a USB memory and a memory card. The memory device 121c or the external memory device 123 may be embodied by a non-transitory computer readable recording medium. Hereafter, the memory device 121c and the external memory device 123 are collectively referred to as recording media. In the present specification, the term “recording media” may indicate only the memory device 121c, indicate only the external memory device 123, and indicate both of the memory device 121c and the external memory device 123. Instead of the external memory device 123, a communication means such as the Internet and a dedicated line may be used to provide the program to the computer.

### (2) Substrate Processing (Film-Forming Process)

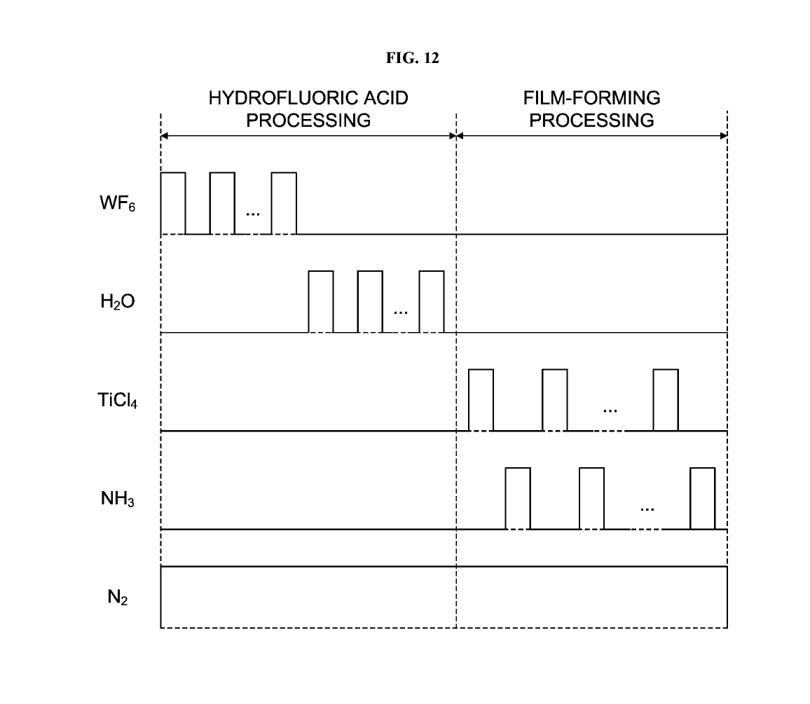

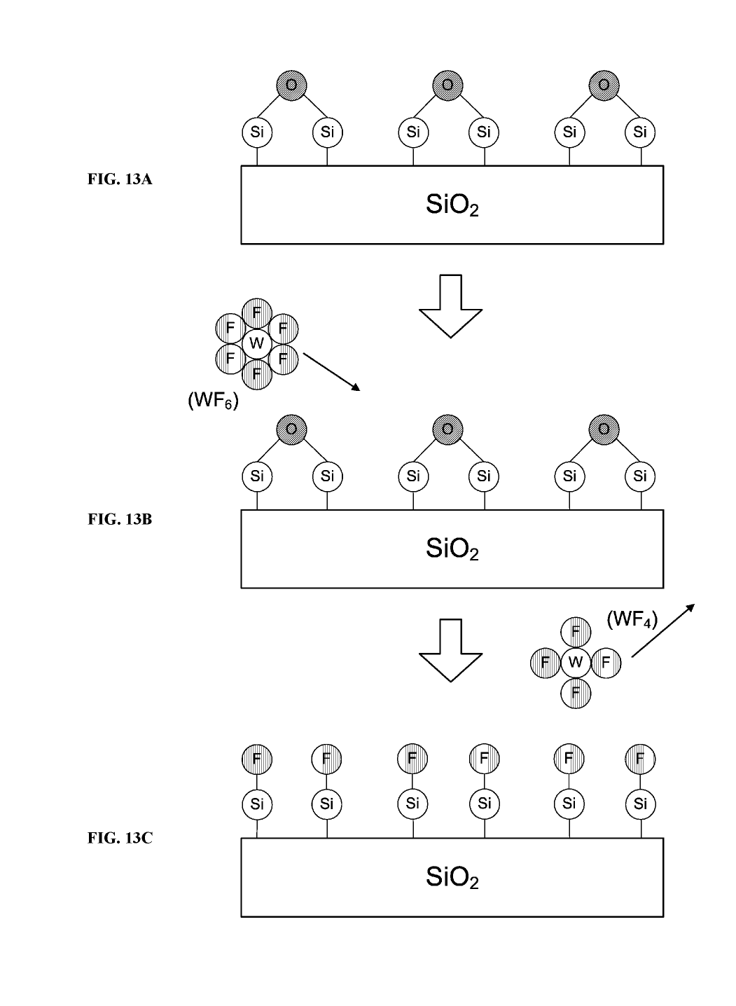

Hereinafter, an exemplary sequence of a substrate processing (film-forming process) of forming a film on the wafer 200, which is a part of manufacturing processes of a semiconductor device, will be described with reference to FIG. 12. According to the exemplary sequence of the substrate processing, a titanium nitride (TiN) film is formed on the wafer 200 on which a silicon oxide (SiO₂) film is formed as the base film (underlying film). The exemplary sequence is performed by using the process furnace 202 of the substrate processing apparatus 10 described above. Hereinafter, the components of the substrate processing apparatus 10 are controlled by the controller 121.

In the substrate processing (manufacturing process of the semiconductor device) according to the embodiments, the titanium nitride film is formed on the base film formed on the wafer 200 by performing: (a) loading the wafer 200 having the silicon oxide film (SiO₂) serving as the base film formed thereon into the process chamber 201; (b) forming halogen terminated sites on the surface of the wafer 200 having the base film formed thereon by supplying the tungsten hexafluoride (WF₆) gas serving as the halogen-containing gas to the wafer 200 to break the bond of the base film and by bonding a halogen component (fluorine component) contained in the halogen-containing gas to the portion of the base film where the bond is broken; (c) terminating the surface of the wafer 200 with hydroxyl group (OH group) by supplying the water vapor gas serving as the OH-containing gas containing the oxygen component and the hydrogen component to the wafer 200 to desorb the halogen component and bonding the hydroxyl group to empty dangling bond; and (d) forming the titanium nitride film on the surface of the wafer 200 with the OH-terminated sites.

The steps (b) forming the halogen terminated sites on the surface of the wafer 200 and (c) terminating the surface of the wafer 200 with the hydroxyl group may be performed a plurality of times, respectively. In the present specification, the steps (b) forming the halogen terminated sites on the surface of the wafer 200 and (c) terminating the surface of the wafer 200 with the hydroxyl group may be collectively referred to as a “hydrofluoric acid processing”, and the step (d) forming the titanium nitride film on the surface of the wafer 200 with the OH-terminated sites may be referred to as the “film-forming processing”.

In the present specification, the term “wafer” may refer to “a wafer itself” or refer to “a wafer and a stacked structure (aggregated structure) of predetermined layers or films formed on the surface of the wafer”. In the present specification, the term “surface of wafer” refers to “a surface (exposed surface) of a wafer” or “the surface of a predetermined layer or a film formed on the wafer”. In the present specification, the terms “substrate” and “wafer” may be used as substantially the same meaning.

### Wafer Loading Step

The wafers including the wafer 200 are charged into the boat 217 (wafer charging). After the boat 217 is charged with wafers including the wafer 200, the boat 217 supporting the wafers is elevated by the boat elevator 115 and loaded into the process chamber 201 (boat loading), as shown in FIG. 9. With the boat 217 loaded, the seal cap 219 seals the lower end opening of the reaction tube 203 via the O-ring 220b.

### Pressure and Temperature Adjusting Step

The vacuum pump 246 vacuum-exhausts the process chamber 201 until the inner pressure of the process chamber 201 reaches a desired pressure (vacuum degree). In the pressure and temperature adjusting step, the inner pressure of the process chamber 201 is measured by the pressure sensor 245, and the APC valve 243 is feedback-controlled based on the measured pressure (pressure adjusting). The vacuum pump 246 is continuously operated until at least the processing of the wafer 200 is completed. The heater 207 heats the process chamber 201 such that the inner temperature of the process chamber 201 reaches a desired predetermined temperature. The amount of current supplied to the heater 207 is feedback-controlled based on the temperature detected by the temperature sensor 263 such that the inner temperature of the process chamber 201 has a desired temperature distribution (temperature adjusting). The heater 207 continuously heats the process chamber 201 until at least the processing of the wafer 200 is completed.

### A. Hydrofluoric Acid Processing

Hereinafter, the hydrofluoric acid processing will be described. The OH-terminated sites having a high number density are generated on the surface of the silicon oxide film serving as the base film by the hydrofluoric acid processing.

A-1: Halogen Termination Step (Supplying WF₆ Gas)

The valve 314 is opened to supply WF₆ gas, which is one of the process gases, into the gas supply pipe 310. A flow rate of the WF₆ gas is adjusted by the MFC 312. The WF₆ gas with the flow rate thereof adjusted is supplied into the process chamber 201 through the gas supply holes 410a of the nozzle 410 to supply the WF₆ gas onto the wafer 200, and then is exhausted through the exhaust pipe 231. Simultaneously, the valve 514 is opened to supply the inert gas such as N₂ gas into the gas supply pipe 510. A flow rate of the N₂ gas is adjusted by the MFC 512. The N₂ gas with the flow rate thereof adjusted is supplied with the WF₆ gas into the process chamber 201, and is exhausted through the exhaust pipe 231. In order to prevent the WF₆ gas from entering the nozzles 420 and 430, the valves 524 and 534 are opened to supply the N₂ gas into the gas supply pipes 520 and 530. The N₂ gas is supplied into the process chamber 201 through the gas supply pipes 320 and 330 and the nozzles 420 and 430, and is exhausted through the exhaust pipe 231.

In the halogen termination step, the APC valve 243 is appropriately controlled to adjust the inner pressure of the process chamber 201 to a predetermined pressure. For example, the predetermined pressure of the process chamber 201 may range from 5 Pa to 1,000 Pa. The flow rate of the WF₆ gas supplied into the process chamber 201 is adjusted by the MFC 312 to a predetermined flow rate. For example, the predetermined flow rate of the WF₆ gas may range from 5 sccm to 500 sccm. The flow rates of the N₂ gas supplied into the process chamber 201 are adjusted by the MFCs 512, 522 and 532 to predetermined flow rates, respectively. For example, the predetermined flow rates of the N₂ gas supplied into the process chamber 201 may range from 10 sccm to 1,000 sccm, respectively. The temperature of the heater 207 is adjusted such that the temperature of the wafer 200 may become a predetermined temperature. The predetermined temperature of the wafer 200 may range from 200° C. to 400° C.

In the halogen termination step, only the WF₆ gas and the N₂ gas are supplied into the process chamber 201. By supplying the WF₆ gas, the bonds on the surface of the wafer 200 are broken. By bonding the fluorine component (F) contained in the WF₆ gas to the portion of the base film where the bonds are broken, the halogen terminated sites are formed on the surface of the wafer 200.

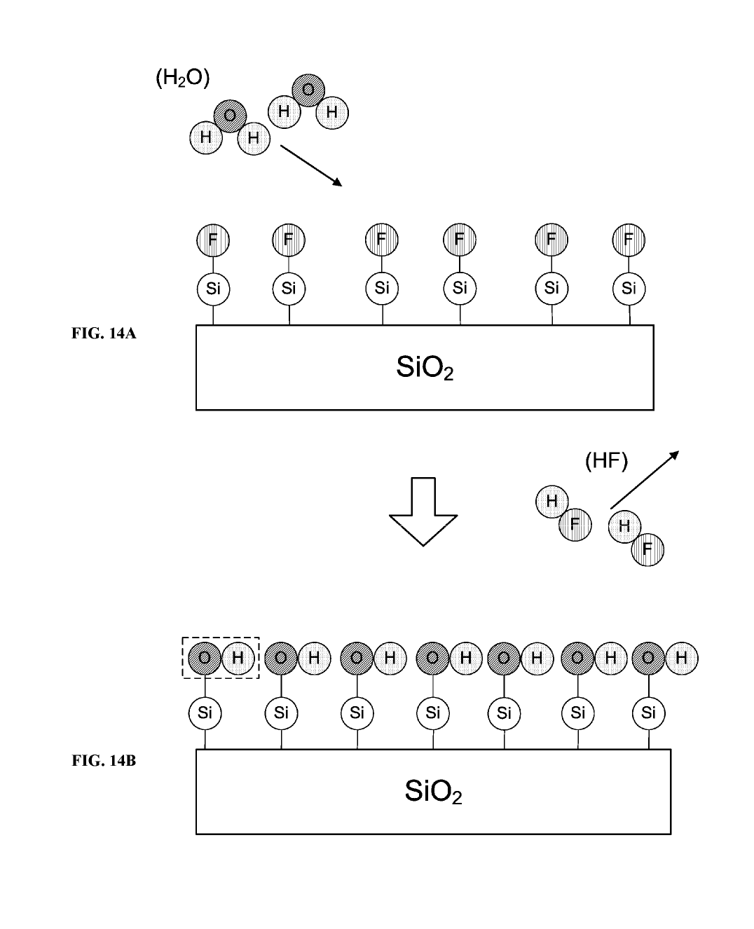

FIGS. 13A through 13C schematically illustrate the states of the surface of the wafer 200 when the halogen terminated sites are formed in the halogen termination step. FIG. 13A schematically illustrates the state of the surface of the wafer 200 having the silicon oxide film formed thereon before the surface of the wafer 200 is exposed to the WF₆ gas. FIG. 13B schematically illustrates the state of the surface of the wafer 200 immediately after the WF₆ gas is supplied to the surface of the wafer 200. FIG. 13C schematically illustrates the state of the surface of the wafer 200 after the surface of the wafer 200 is exposed to the WF₆ gas.

After a predetermined time has elapsed from the supply of the WF₆ gas, the valve 314 of the gas supply pipe 310 is closed to stop the supply of the WF₆ gas.

Referring to FIG. 13C, the surface of the silicon oxide film formed on the wafer 200 is terminated by the halogen component (that is, fluorine component) (hereinafter, also referred to as “halogen-terminated”) after the surface of the wafer 200 is exposed to the WF₆ gas.

A-2: First Purging Step (Removing Residual Gas)

Subsequently, after the supply of the WF₆ gas is stopped, a purging process for exhausting the gas in the process chamber 201 is performed. In the first purging step, with the APC valve 243 of the exhaust pipe 231 open, the vacuum pump 246 vacuum-exhausts the inside of the process chamber 201 to remove a residual WF₆ gas which did not react or WF₄ gas which contributed to the termination of the surface of the silicon oxide film with the halogen component from the process chamber 201. By maintaining the valves 514 and 524 open, the N₂ gas is continuously supplied into the process chamber 201. The N₂ gas serves as a purge gas, which improves the efficiency of removing the residual WF₆ gas which did not react or the WF₄ gas which contributed to the termination of the surface of the silicon oxide film from the process chamber 201.

### Performing a Predetermined Number of Times

By performing a cycle wherein the halogen termination step and the first purging step are performed sequentially a predetermined number of times (n times, n is a natural number equal to or greater than 1), the surface of the silicon oxide film formed on the wafer 200 is halogen-terminated.

In the halogen termination step of forming the halogen terminated sites, the supply of the WF₆ gas and the exhaust of the WF₆ gas are alternately performed. When by-products (for example, WF₄) generated by the reaction of the WF₆ gas and the silicon oxide film serving as the base film stay on the wafer 200, the by-products may disturb the OH-containing gas from reaching the wafer 200. Therefore, the by-products are exhausted by alternately performing the supply of the WF₆ gas and the exhaust of the WF₆ gas. By exhausting the by-products, it is possible to prevent the harmful effects caused by the by-products, and as a result, it is possible to form the halogen terminated sites continuously.

A-3: OH Termination Step (Supplying H₂O Gas)

Subsequently, after the residual gas is removed from the process chamber 201, the valve 324 is opened to supply H₂O gas, which is one of the process gases, into the gas supply pipe 320. A flow rate of the H₂O gas is adjusted by the MFC 322. The H₂O gas with the flow rate thereof adjusted is supplied into the process chamber 201 through the gas supply holes 420a of the nozzle 420 to supply the H₂O gas onto the wafer 200, and then is exhausted through the exhaust pipe 231. Simultaneously, the valve 524 is opened to supply N₂ gas into the gas supply pipe 520. A flow rate of the N₂ gas is adjusted by the MFC 522. The N₂ gas with the flow rate thereof adjusted is supplied with the H₂O gas into the process chamber 201, and is exhausted through the exhaust pipe 231. In order to prevent the H₂O gas from entering the nozzles 410 and 430, the valves 514 and 534 are opened to supply the N₂ gas into the gas supply pipes 510 and 530. The N₂ gas is supplied into the process chamber 201 through the gas supply pipes 310 and 330 and the nozzles 410 and 430, and is exhausted through the exhaust pipe 231.

In the OH termination step, the APC valve 243 is appropriately controlled to adjust the inner pressure of the process chamber 201 to a predetermined pressure. For example, the predetermined pressure of the process chamber 201 may range from 100 Pa to 1,000 Pa. The flow rate of the H₂O gas supplied into the process chamber 201 is adjusted by the MFC 322 to a predetermined flow rate. For example, the predetermined flow rate of the H₂O gas may range from 10 sccm to 500 sccm. The flow rates of the N₂ gas supplied into the process chamber 201 are adjusted by the MFCs 512, 522 and 532 to predetermined flow rates, respectively. For example, the predetermined flow rates of the N₂ gas supplied into the process chamber 201 may range from 10 sccm to 1,000 sccm, respectively. For example, the time duration of supplying the H₂O gas to the wafer 200 may range from 5 seconds to 1,000 seconds. The temperature of the heater 207 is adjusted such that the temperature of the wafer 200 may become a predetermined temperature. The predetermined temperature of the wafer 200 may range from 200° C. to 400° C.

In the OH termination step, only the H₂O gas and the N₂ gas are supplied into the process chamber 201. The H₂O gas desorbs the halogen component halogen-terminated on the surface of the base film in the halogen termination step, and the OH-terminated sites are formed on the surface of the wafer 200 by bonding the OH group to the empty dangling bonds.

FIGS. 14A and 14B schematically illustrate the states of the surface of the wafer 200 when the OH-terminated sites are formed in the OH termination step. FIG. 143A schematically illustrates the state of the surface of the wafer 200 immediately after the H₂O gas is supplied to the surface of the wafer 200. FIG. 14B schematically illustrates the state of the surface of the wafer 200 after the surface of the wafer 200 is exposed to the H₂O gas.

After a predetermined time has elapsed from the supply of the H₂O gas, the valve 324 of the gas supply pipe 320 is closed to stop the supply of the H₂O gas.

Referring to FIG. 13C, the surface of the silicon oxide film formed on the wafer 200 is terminated by the OH group (hereinafter, also referred to as “OH-terminated”) after the surface of the wafer 200 is exposed to the H₂O gas.

A-4: Second Purging Step (Removing Residual Gas)

Subsequently, after the supply of the H₂O gas is stopped, a purging process for exhausting the gas in the process chamber 201 is performed in the same manners as the first purging step. In the second purging step, with the APC valve 243 of the exhaust pipe 231 open, the vacuum pump 246 vacuum-exhausts the inside of the process chamber 201 to remove a residual H₂O gas which did not react or HF gas generated by the OH termination of the halogen-terminated silicon oxide film from the process chamber 201. By maintaining the valves 514 and 524 open, the N₂ gas is continuously supplied into the process chamber 201. The N₂ gas serves as the purge gas, which improves the efficiency of removing various residual gases such as the residual H₂O gas and the HF gas from the process chamber 201.

### Performing a Predetermined Number of Times

By performing a cycle wherein the OH termination step and the second purging step are performed sequentially a predetermined number of times (m times, m is a natural number equal to or greater than 1), the halogen-terminated surface of the wafer 200 is OH-terminated.

In the OH termination step of forming the OH-terminated sites, the supply of the H₂O gas and the exhaust of the H₂O gas are alternately performed. When the H₂O gas reacts with the halogen terminated sites, positively charged hydrogen component and negatively charged fluorine component are generated on the surface of the silicon oxide film, and the separated hydrogen component tends to bond with the fluorine component on the surface of the silicon oxide film. When the separated hydrogen component bonds with the fluorine component on the surface of the silicon oxide film, the separated hydrogen component bonded with the fluorine component interferes with the bonding between the OH group and silicon (Si) of the silicon oxide film. Therefore, by exhausting the positively charged hydrogen component or the negatively charged fluorine component, it is possible to prevent the occurrence of the harmful effects caused by the positively charged hydrogen component or the negatively charged fluorine component, and as a result, it is possible to form the OH-terminated sites continuously.

According to the embodiments, by providing the first purging step described above between the halogen termination step and the OH termination step, the inner atmosphere of the process chamber 201 where the wafers including the wafer 200 is exhausted between the halogen termination step of forming the halogen terminated sites and the OH termination step of terminating the surface of the wafer 200 with the hydroxyl group. When the WF₆ serving as the halogen-containing gas and the H₂O gas serving as the OH-containing gas are simultaneously present in the process chamber 201, the gases react with each other in the process chamber 201, and by-products generated by the reaction stay on the wafer 200 and hinder the H₂O gas from reaching the wafer 200. In addition, when the by-products adhere to the wafer 200 and the by-products include components different from those of the film to be formed, the by-products serve as impurities in the film to be formed. Therefore, by providing an exhaust step such as the first purging step between the halogen termination step and the OH termination step to exhaust the by-products, it is possible to prevent the occurrence of the harmful effects caused by the by-products.

In addition, when the HF gas is generated by the reaction between the halogen-containing gas and the OH-containing gas, the exhaust pipe 231 is corroded by the HF gas. Therefore, by providing the exhaust step such as the first purging step between the halogen termination step and the OH termination step to exhaust the by-products generated by the reaction, it is possible to prevent the occurrence of the harmful effects caused by the by-products.

### B. Film-Forming Processing

Subsequently, the titanium nitride (TiN) film is formed on the wafer 200. The surface of the silicon oxide film formed on the wafer 200 is OH-terminated by the hydrofluoric acid processing.

B-1: First Step (Supplying TiCl₄ Gas)

The valve 314 is opened to supply TiCl₄ gas serving as the source gas, which is one of the process gases, into the gas supply pipe 310. A flow rate of the TiCl₄ gas is adjusted by the MFC 312. The TiCl₄ gas with the flow rate thereof adjusted is supplied into the process chamber 201 through the gas supply holes 410a of the nozzle 410 to supply the TiCl₄ gas onto the wafer 200, and then is exhausted through the exhaust pipe 231. Simultaneously, the valve 514 is opened to supply the inert gas such as N₂ gas into the gas supply pipe 510. A flow rate of the N₂ gas is adjusted by the MFC 512. The N₂ gas with the flow rate thereof adjusted is supplied with the TiCl₄ gas into the process chamber 201, and is exhausted through the exhaust pipe 231. In order to prevent the TiCl₄ gas from entering the nozzles 420 and 430, the valves 524 and 534 are opened to supply the N₂ gas into the gas supply pipes 520 and 530. The N₂ gas is supplied into the process chamber 201 through the gas supply pipes 320 and 330 and the nozzles 420 and 430, and is exhausted through the exhaust pipe 231.

In the first step, the APC valve 243 is appropriately controlled to adjust the inner pressure of the process chamber 201 to a predetermined pressure. For example, the predetermined pressure of the process chamber 201 may range from 10 Pa to 1,000 Pa. For example, the inner pressure of the process chamber 201 is set to 50 Pa. The flow rate of the TiCl₄ gas supplied into the process chamber 201 is adjusted by the MFC 322 to a predetermined flow rate. For example, the predetermined flow rate of the TiCl₄ gas may range from 0.01 slm to 1 slm. The flow rates of the N₂ gas supplied into the process chamber 201 are adjusted by the NIFCs 512, 522 and 532 to predetermined flow rates, respectively. For example, the predetermined flow rates of the N₂ gas supplied into the process chamber 201 may range from 0.1 slm to 2 slm, respectively. For example, the time duration of supplying the TiCl₄ gas to the wafer 200 may range from 0.1 second to 60 seconds. The temperature of the heater 207 is adjusted such that the temperature of the wafer 200 may become a predetermined temperature. The predetermined temperature of the wafer 200 may range from 200° C. to 600° C. For example, the predetermined temperature of the wafer 200 is set to 250° C.

In the first step, only the TiCl₄ gas and the N₂ gas are supplied into the process chamber 201. By supplying the TiCl₄ gas, a titanium (Ti)-containing layer is formed on the wafer 200 (that is, on the surface of the base film formed on the wafer 200). The titanium-containing layer may include only a titanium (Ti) layer containing chlorine (Cl), only an adsorption layer of the TiCl₄ or both of them.

B-2: Second Step (Removing Residual Gas)

After the titanium-containing layer is formed, the valve 314 is closed to stop the supply of the TiCl₄ gas into the process chamber 201. Then, a residual TiCl₄ gas in the process chamber 201 which did not react or which contributed to the formation of the titanium-containing layer or the reaction by-products in the process chamber 201 are removed from the process chamber 201.

B-3: Third Step (Supplying NH₃ Gas)

Subsequently, after the residual gas is removed from the process chamber 201, the valve 334 is opened to supply NH₃ gas serving as the reactive gas, which is one of the process gases, into the gas supply pipe 330. A flow rate of the NH₃ gas is adjusted by the MFC 332. The NH₃ gas with the flow rate thereof adjusted is supplied into the process chamber 201 through the gas supply holes 430a of the nozzle 430 to supply the NH₃ gas onto the wafer 200, and then is exhausted through the exhaust pipe 231. Simultaneously, the valve 534 is opened to supply N₂ gas into the gas supply pipe 530. A flow rate of the N₂ gas is adjusted by the MFC 532. The N₂ gas with the flow rate thereof adjusted is supplied with the NH₃ gas into the process chamber 201, and is exhausted through the exhaust pipe 231. In order to prevent the NH₃ gas from entering the nozzles 410 and 420, the valves 514 and 524 are opened to supply the N₂ gas into the gas supply pipes 510 and 520. The N₂ gas is supplied into the process chamber 201 through the gas supply pipes 310 and 320 and the nozzles 410 and 420, and is exhausted through the exhaust pipe 231.

In the third step, the APC valve 243 is appropriately controlled to adjust the inner pressure of the process chamber 201 to a predetermined pressure. For example, the predetermined pressure of the process chamber 201 may range from 10 Pa to 2,000 Pa. For example, the inner pressure of the process chamber 201 is set to 50 Pa. The flow rate of the NH₃ gas supplied into the process chamber 201 is adjusted by the MFC 322 to a predetermined flow rate. For example, the predetermined flow rate of the NH₃ gas may range from 0.1 slm to 10 slm. The flow rates of the N₂ gas supplied into the process chamber 201 are adjusted by the MFCs 512, 522 and 532 to predetermined flow rates, respectively. For example, the predetermined flow rates of the N₂ gas supplied into the process chamber 201 may range from 0.1 slm to 10 slm, respectively. For example, the time duration of supplying the NH₃ gas to the wafer 200 may range from 10 seconds to 200 seconds. In the third step, the temperature of the heater 207 is adjusted to the same temperature as the first step (supplying TiCl₄ gas).

In the third step, only the NH₃ gas and the N₂ gas are supplied into the process chamber 201. A substitution reaction occurs between the NH₃ gas and at least a portion of the titanium-containing layer formed on the wafer 200 in the first step. During the substitution reaction, titanium contained in the titanium-containing layer and nitrogen contained in the NH₃ gas are bonded. As a result, a titanium nitride (TiN) layer containing titanium (Ti) and nitrogen (N) is formed on the wafers 200.

B-4: Fourth Step (Removing Residual Gas)

Subsequently, after the titanium nitride layer is formed, the valve 334 is closed to stop the supply of the NH₃ gas into the process chamber 201. Then, a residual NH₃ gas in the process chamber 201 which did not react or which contributed to the formation of the titanium nitride layer or the reaction by-products in the process chamber 201 are removed from the process chamber 201 in the same manners as the second step.

### Performing a Predetermined Number of Times

By performing a cycle wherein the first step, the second step, the third step and the fourth step are performed non-simultaneously in this order a predetermined number of times (k times, k is a natural number equal to or greater than 1), a titanium nitride layer having a predetermined thickness (for example, from 0.5 nm to 5.0 nm) is formed on the wafer 200. It is preferable that the cycle is performed a plurality of times.

### Purging and Returning to Atmospheric Pressure Step

The N₂ gas is supplied into the process chamber 201 through each of the gas supply pipes 510, 520 and 530, and then is exhausted through the exhaust pipe 231. The N₂ gas serves as the purge gas. The process chamber 201 is thereby purged such that the residual gas or the by-products remaining in the process chamber 201 are removed from the process chamber 201 (purging). Thereafter, the inner atmosphere of the process chamber 201 is replaced with the inert gas (replacing with inert gas), and the inner pressure of the process chamber 201 is returned to atmospheric pressure (returning to atmospheric pressure).

### Wafer Unloading Step

Thereafter, the seal cap 219 is lowered by the boat elevator 115 and the lower end of the reaction tube 203 is opened. The boat 217 with the processed wafers including the wafer 200 charged therein is unloaded out of the reaction tube 203 through the lower end of the reaction tube 203 (boat unloading). Then, the processed wafers including the wafer 200 are discharged from the boat 217 (wafer discharging).

### (3) Effects According to the Embodiments

In the embodiments, first, the surface of the base film is halogen-terminated by the WF₆ gas, and then the surface of the base film is OH-terminated by the water vapor (H₂O gas). The H₂O alone does not have a sufficient force to break the bonds on the surface of the base film. Since the activation energy for forming the OH-terminated sites on the base film by reacting with the H₂O is high, it is impossible to form the OH-terminated sites on the base film with sufficient density. Therefore, first, the surface of the base film is halogen-terminated by the WF₆ having a strong force to break the bonds on the surface of the base film. Then, by the reaction of the halogen-terminated sites with the H₂O in which the activation energy for replacing the halogen-terminated sites with the OH-terminated sites is low, it is possible to easily replace the halogen-terminated sites with the OH-terminated sites.

As a result, according to the embodiments, the surface of the base film before forming the film is OH-terminated to generate the adsorption sites with high number density. Therefore, according to the embodiments, it is possible to provide the technique capable of forming the semiconductor device having the film with high uniformity.

### (4) Experimental Examples

Subsequently, the difference between a case where is formed on the silicon oxide film where the OH-terminated sites are formed thereon and a case where the TiN film is formed on the silicon oxide film where the OH-terminated sites are not formed thereon will be described. The OH-terminated sites may be removed by an annealing process at 800° C. Therefore, the wafer having subjected to the annealing process at 800° C. after the hydrofluoric acid processing is used as the wafer on which the OH-terminated sites are not formed.

After the hydrofluoric acid processing, the OH group used as the adsorption sites covers the surface of the silicon oxide film serving as the base film as shown in FIG. 8A. However, after performing the annealing process at 800° C., as shown in FIG. 8B, there is almost no OH group and the defect site (dangling bonds) used as the adsorption sites partially exists on the surface of the silicon oxide film.

The result of forming the TiN film on the silicon oxide film after the hydrofluoric acid processing is performed and the result of forming the TiN film on the silicon oxide film after the annealing process at 800° C. after the hydrofluoric acid processing is performed will be described below. In the experimental examples, as described in the above embodiments, the TiN film having a thickness of about 2 nm is formed at a temperature of 250° C. and a pressure of 50 Pa by using the TiCl₄ as the titanium source and the NH₃ as the nitrogen source.

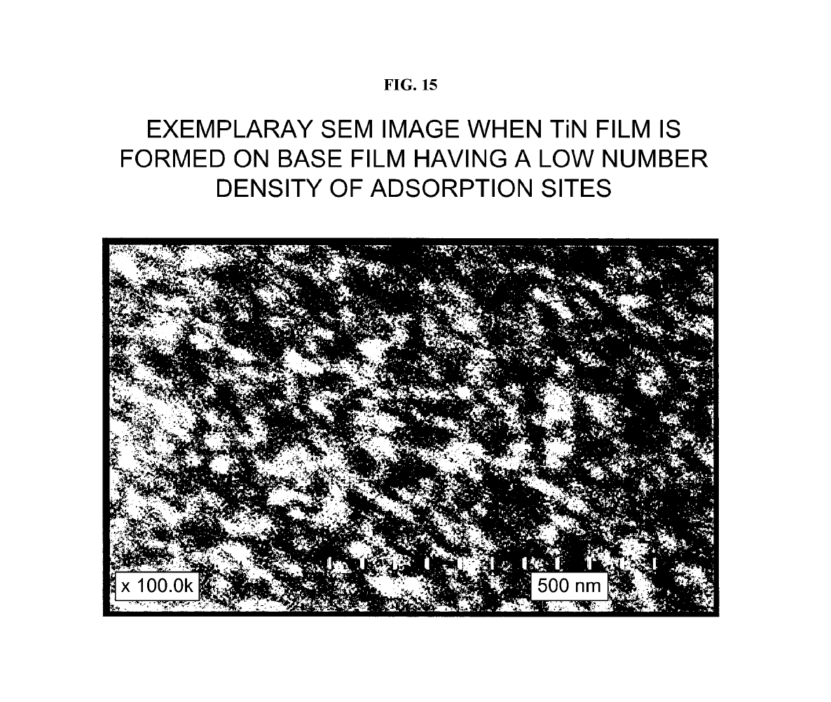

FIG. 15 illustrates the result of forming the TiN film after performing the annealing process at 800° C., that is, an SEM (Scanning Electron Microscope) image of the surface of the oxide film (thermal oxide film) after the TiN film is formed. The TiN film is formed on the base film having a low number density of the adsorption sites. Referring to the SEM image shown in FIG. 15, the film is formed discontinuously since the film-forming processing for forming the titanium nitride film (TiN film) is performed in a state in which the number density of the OH group serving as the adsorption sites is low.

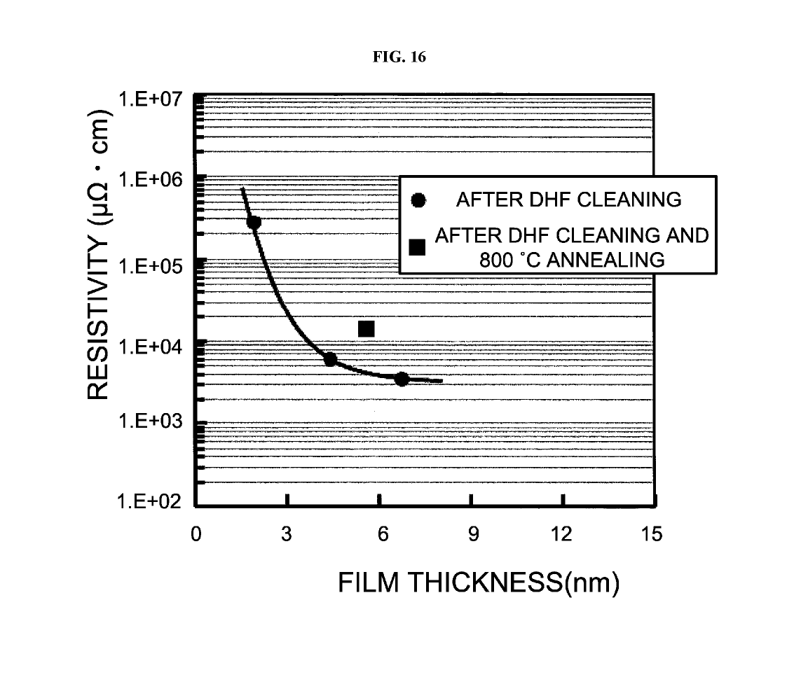

Subsequently, FIG. 16 illustrates the resistivity of the TiN film formed after the hydrofluoric acid processing and the resistivity of the TiN film formed after the annealing process at 800° C. Referring to FIG. 16, the resistivity of the TiN film formed on the surface of the base film in which the OH group is removed by the annealing process at 800° C. is higher than that of the TiN film formed on the surface of the base film covered with the OH group after the hydrofluoric acid processing. The resistivity of the TiN film formed on the surface of the base film in which the OH group is removed by the annealing process at 800° C. is high because the film is formed discontinuously. From the above results, it is confirmed that a uniform and continuous film can be obtained by performing the OH termination of the surface of the base film.

### Modified Examples

While the embodiments are described by way of an example in which the tungsten hexafluoride (WF₆) gas is used as the halogen-containing gas, the above-described technique is not limited thereto. The above-described technique may be applied when other gases such as chlorine trifluoride (ClF₃) gas, nitrogen trifluoride (NF₃) gas, hydrogen fluoride (HF) gas and fluorine (F₂) gas are used as the halogen-containing gas.

Similarly, while the embodiments are described by way of an example in which the water vapor (H₂O) gas is used as the OH-containing gas containing the oxygen component and the hydrogen component, the above-described technique is not limited thereto. The above-described technique may be applied when other gases such as hydrogen peroxide (H₂O₂) gas are used as the OH-containing gas.

While the embodiments are described by way of an example in which the surface of the silicon oxide film (SiO₂) serving as the base film is OH-terminated, the above-described technique is not limited thereto. The above-described technique may be applied when a film such as a silicon (Si) film, a silicon nitride (SiN) film, an aluminum oxide (AlO) film, a hafnium oxide (HfO) film and a zirconium oxide (ZrO₂) film is used as the base film and the surface of the base film is OH-terminated

While the technique is described by way of the above-described embodiments and the modified examples, the above-described technique is not limited thereto. The above-described embodiments and the modified examples may be appropriately combined.

According to the technique described herein, it is possible to form a semiconductor device with high film uniformity.

What is claimed is:

1. A method of manufacturing a semiconductor device, comprising:
(a) forming halogen terminated sites on a surface of a substrate having a base film formed thereon by supplying a halogen-containing gas to the substrate; and
(b) terminating the surface of the substrate with hydroxyl group by supplying a hydroxyl-containing gas containing an oxygen component and a hydrogen component to the substrate.

2. The method of claim 1, further comprising:
exhausting an atmosphere of a process chamber in which the substrate is accommodated between performing (a) and (b).

3. The method of claim 1, wherein the hydroxyl-containing gas is alternately supplied and exhausted in (b).

4. The method of claim 1, wherein the halogen-containing gas is alternately supplied and exhausted in (a).

5. The method of claim 2, wherein the halogen-containing gas is alternately supplied and exhausted in (a).

6. The method of claim 3, wherein the halogen-containing gas is alternately supplied and exhausted in (a).

7. The method of claim 1, wherein (b) is performed after performing (a).

8. The method of claim 7, further comprising:
(c) supplying a source gas to the substrate; and
(d) supplying a reactive gas to the substrate,
wherein (c) and (d) are performed after performing (b).

9. The method of claim 1, wherein the base film to which the halogen-containing gas is supplied in (a) comprises discontinuous adsorption sites.

10. The method of claim 1, wherein the halogen-containing gas contains a fluorine element.

11. A substrate processing apparatus comprising:
a process chamber wherein a substrate is accommodated;
a halogen-containing gas supply system configured to supply a halogen-containing gas to the process chamber;
a hydroxyl-containing gas supply system configured to supply a hydroxyl-containing gas containing an oxygen component and a hydrogen component; and
a controller configured to control the halogen-containing gas supply system and the hydroxyl-containing gas supply system to perform:
(a) forming halogen terminated sites on a surface of the substrate having a base film formed thereon by supplying the halogen-containing gas to the substrate; and
(b) terminating the surface of the substrate with hydroxyl group by desorbing halogen component and bonding the hydroxyl group to a dangling bond by supplying the hydroxyl-containing gas to the substrate.

12. The substrate processing apparatus of claim 11, further comprising:
an exhaust part configured to exhaust an atmosphere of the process chamber,
wherein the controller is further configured to control the hydroxyl-containing gas supply system and the exhaust part to perform alternately supplying and exhausting the hydroxyl-containing gas in (b).

13. The substrate processing apparatus of claim 11, further comprising:
an exhaust part configured to exhaust an atmosphere of the process chamber,
wherein the controller is further configured to control the halogen-containing gas supply system and the exhaust part to perform alternately supplying and exhausting the halogen-containing gas in (a).

14. The substrate processing apparatus of claim 12, wherein the controller is further configured to control the halogen-containing gas supply system and the exhaust part to perform alternately supplying and exhausting the halogen-containing gas in (a).

15. A non-transitory computer-readable recording medium storing a program that causes, by a computer, a substrate processing apparatus to perform:
(a) forming halogen terminated sites on a surface of a substrate having a base film formed thereon by supplying a halogen-containing gas to a process chamber of the substrate processing apparatus wherein the substrate is accommodated; and
(b) terminating the surface of the substrate with hydroxyl group by supplying a hydroxyl-containing gas containing an oxygen component and a hydrogen component to the substrate.

16. The non-transitory computer-readable recording medium of claim 15, wherein the hydroxyl-containing gas is alternately supplied and exhausted in (b).

17. The non-transitory computer-readable recording medium of claim 15, wherein the halogen-containing gas is alternately supplied and exhausted in (a).

18. The non-transitory computer-readable recording medium of claim 16, wherein the halogen-containing gas is alternately supplied and exhausted in (a).
